(19) United States
(12) Patent Application Publication
(10) Pub. No.: US 2026/0086116 A1
(43) Pub. Date: Mar. 26, 2026

(54) ELECTRICALLY CONDUCTIVE CONTACT PIN

(71) Applicant: POINT ENGINEERING CO., LTD., Asan-Si (KR)

(72) Inventors: Bum Mo AHN, Suwon-Si (KR); Seung Ho PARK, Hwaseong-Si (KR); Sung Hyun BYUN, Suwon-Si (KR)

(73) Assignee: POINT ENGINEERING CO., LTD., Asan-Si (KR)

(21) Appl. No.: 19/406,976

(22) Filed: Dec. 3, 2025

Related U.S. Application Data
(63) Continuation of application No. PCT/KR2023/008404, filed on Jun. 16, 2023.

(51) Int. Cl. G01R 1/067; G01R 1/04

(52) U.S. Cl. CPC G01R 1/06761; G01R 1/0416; G01R 1/06722; G01R 1/06733

(57) ABSTRACT

The present invention provides an electrically conductive contact pin comprising a first end region, a second end region, and a body region positioned between them, wherein the body region includes at least two beam portions spaced apart by a slit and comprises a functional layer inside the slit to prevent local destruction of the beam and improve the current carrying capacity.

### TECHNICAL FIELD

The present invention relates to an electrically conductive contact pin.

### BACKGROUND

The electrical characteristic test of a semiconductor device is performed by a testing apparatus comprising a plurality of electrically conductive contact pins. The test is conducted by bringing the semiconductor device (semiconductor wafer or semiconductor package) close to the testing apparatus and contacting the electrically conductive contact pins with the external terminals (solder balls or bumps, etc.) of the semiconductor device. Examples of the testing apparatus include a probe card or a test socket, and the electrically conductive contact pins include probe pins or socket pins, but are not limited thereto.

More specifically, the electrical characteristic test of a semiconductor device is performed by bringing the semiconductor device close to a testing apparatus in which a plurality of electrically conductive contact pins are formed on a circuit board, and contacting each electrically conductive contact pin with a corresponding external terminal on the semiconductor device. When the electrically conductive contact pins and the external terminals are brought into contact, after reaching a state where they begin to contact, the process of further bringing the semiconductor device closer to the testing apparatus is performed. This process is called overdrive. Overdrive is a process that elastically deforms the electrically conductive contact pins, and by performing overdrive, even if there are variations in the height of the external terminals or the height of the electrically conductive contact pins, all the electrically conductive contact pins can be reliably brought into contact with the external terminals. Additionally, during overdrive, the electrically conductive contact pins elastically deform, and their tips move on the external terminals, thereby performing scrubbing. This scrubbing removes the oxide film on the surface of the external terminals and reduces contact resistance.

FIG. 1A is a plan view of an electrically conductive contact pin 1 according to the prior art, FIG. 1B is a cross-sectional view along A-A′ of FIG. 1A, FIG. 1C is a plan view of an electrically conductive contact pin 1 with a slit 32 formed according to the prior art, and FIG. 1D is a cross-sectional view along A-A′ of FIG. 1C.

The electrically conductive contact pin 1 shown in FIGS. 1A and 1B may be composed of a single material metal. The electrically conductive contact pin 1 must elastically deform during the overdrive process. Therefore, the single material metal constituting the electrically conductive contact pin 1 may be selected from metals such as rhodium (Rh), platinum (Pt), iridium (Ir), palladium (Pd), nickel (Ni), manganese (Mn), tungsten (W), phosphorus (P), or their alloys, or palladium-cobalt (PdCo) alloy, palladium-nickel (PdNi) alloy, nickel-phosphorus (NiP) alloy, nickel-manganese (NiMn), nickel-cobalt (NiCo), or nickel-tungsten (NiW) alloy, considering the elastic deformation.

Shortening the length of such an electrically conductive contact pin 1 can reduce its inductance and improve the high-frequency characteristics of the test signal. However, if the length of the electrically conductive contact pin 1 is shortened while trying to secure a sufficient amount of overdrive, there is a problem that the electrically conductive contact pin 1 may undergo plastic deformation during overdrive or damage the external terminals. By reducing the width of the electrically conductive contact pin 1, it is possible to consider suppressing the stress during overdrive. When the electrically conductive contact pin 1 is curved in the width direction, the maximum stress occurs on the outer side of the curved portion. Since this stress depends on the width of the electrically conductive contact pin 1, reducing the width of the electrically conductive contact pin 1 can reduce the stress during overdrive. In other words, even if the length of the electrically conductive contact pin 1 is shortened, reducing its width accordingly can secure the desired amount of overdrive. However, reducing the width of the electrically conductive contact pin causes its cross-sectional area to decrease, leading to a problem of reduced penetration pressure during overdrive and deterioration of the allowable current characteristics over time. To solve such problems, it is necessary to increase the thickness of the electrically conductive contact pin to secure the cross-sectional area. However, in the case of electrically conductive contact pins manufactured using conventional photoresist molds, there is a limit to increasing the thickness of the electrically conductive contact pin.

To solve the above problems, as shown in FIGS. 1C and 1D, it is desirable to form a slit in the body region 13 of the electrically conductive contact pin 1. This can reduce the stress generated during bending and secure the desired amount of overdrive. However, the electrically conductive contact pin 1 shown in FIGS. 1C and 1D has a problem in that the slit 32 formed in the body region 13 causes local destruction of the beam and cannot improve the current carrying capacity.

### PRIOR ART DOCUMENTS

### Patent Document

Korean Patent No. 10-2164373 Registered Patent Gazette

### SUMMARY

The present invention has been devised to solve the problems of the prior art described above, and its purpose is to provide an electrically conductive contact pin comprising a functional layer inside a slit to prevent local destruction of the beam.

In addition, the present invention aims to provide an electrically conductive contact pin comprising a functional layer inside a slit to improve the current carrying capacity.

In order to achieve the above-described objectives, the electrically conductive contact pin according to the present invention comprises a first end region, a second end region, and a body region positioned between the first and second end regions, wherein the body region comprises at least two beam portions, and adjacent beam portions are spaced apart from each other by a slit, and comprises a functional layer provided inside the slit.

In addition, the functional layer has an electrical conductivity greater than the electrical conductivity of the beam portion.

In addition, the functional layer has an elastic modulus smaller than the elastic modulus of the beam portion.

In addition, the beam portion is provided with a plurality of different metal layers stacked, and the functional layer is formed of a single metal layer.

In addition, the beam portion comprises a first metal layer and a second metal layer, wherein the first metal layer is formed of a metal selected from rhodium (Rh), platinum (Pt), iridium (Ir), palladium (Pd), nickel (Ni), manganese (Mn), tungsten (W), phosphorus (P) or alloys thereof, or palladium-cobalt (PdCo) alloy, palladium-nickel (PdNi) alloy, nickel-phosphorus (NiP) alloy, nickel-manganese (NiMn), nickel-cobalt (NiCo), or nickel-tungsten (NiW) alloy, the second metal layer is formed of a metal selected from copper (Cu), silver (Ag), gold (Au), or alloys thereof, and the functional layer is formed of a metal selected from copper (Cu), silver (Ag), gold (Au), or alloys thereof.

In addition, the functional layer is composed of a different material from a metal layer constituting the beam portion.

In addition, the functional layer has the same material as any one of a plurality of metal layers constituting the beam portion.

In addition, the functional layer contacts a plurality of metal layers provided in a height direction of the beam portion at a bonding surface with the beam portion.

In addition, the functional layer is provided entirely in the slit.

In addition, the functional layer is provided partially among a plurality of the slits.

In addition, the functional layer is provided partially in a length direction of the slit.

In addition, the functional layer is provided partially in a thickness direction of the slit.

In addition, the beam portion is elastically deformed by a pressing force applied to the electrically conductive contact pin.

In addition, the beam portion and the functional layer are alternately arranged.

In addition, the beam portion and the functional layer are arranged parallel to each other.

In addition, the body region comprises a spring portion having a curved portion, and the slit is provided in the curved portion.

The present invention provides an electrically conductive contact pin comprising a functional layer inside the slit to prevent local destruction of the beam.

In addition, the present invention provides an electrically conductive contact pin comprising a functional layer inside the slit to improve the current carrying capacity.

### BRIEF DESCRIPTION OF THE DRAWINGS

FIG. 1A is a plan view of an electrically conductive contact pin according to the prior art, and FIG. 1B is a sectional view taken along line A-A′ of FIG. 1A.

FIG. 1C is a plan view of an electrically conductive contact pin according to the prior art, and FIG. 1D is a sectional view taken along line A-A′ of FIG. 1C.

FIG. 2A is a plan view of an electrically conductive contact pin according to a preferred first embodiment of the present invention, and FIG. 2B is a sectional view taken along line A-A′ of FIG. 2A.

FIG. 3A is a plan view of an electrically conductive contact pin according to a preferred first embodiment of the present invention, and FIG. 3B is a sectional view taken along line A-A′ of FIG. 3A.

FIG. 4A is a plan view illustrating a state in which a first internal space is formed in a mold, as a drawing for explaining a manufacturing method of an electrically conductive contact pin according to a preferred first embodiment of the present invention, and FIG. 4B is a sectional view taken along line A-A′ of FIG. 4A.

FIG. 5A is a plan view illustrating a state in which multilayer plating is performed in the first internal space, as a drawing for explaining a manufacturing method of an electrically conductive contact pin according to a preferred first embodiment of the present invention, and FIG. 5B is a sectional view taken along line A-A′ of FIG. 5A.

FIG. 6A is a plan view illustrating a state in which a second internal space is formed by removing a part of the mold, as a drawing for explaining a manufacturing method of an electrically conductive contact pin according to a preferred first embodiment of the present invention, and FIG. 6B is a sectional view taken along line A-A′ of FIG. 6A.

FIG. 7A is a plan view illustrating a state in which a functional layer is formed in the second internal space, as a drawing for explaining a manufacturing method of an electrically conductive contact pin according to a preferred first embodiment of the present invention, and FIG. 7B is a sectional view taken along line A-A′ of FIG. 7A.

FIG. 8 is a side view of an electrically conductive contact pin according to a preferred first embodiment of the present invention.

FIG. 9A is a plan view illustrating a state in which a functional layer is partially provided among a plurality of slits in an electrically conductive contact pin according to a preferred first embodiment of the present invention, and FIG. 9B is a sectional view taken along line A-A′ of FIG. 9A.

FIG. 9C is a plan view illustrating a state in which a functional layer is partially provided among a plurality of slits in an electrically conductive contact pin according to a preferred first embodiment of the present invention, and FIG. 9D is a sectional view taken along line A-A′ of FIG. 9C.

FIG. 9E is a plan view illustrating a state in which a functional layer is partially provided among a plurality of slits in an electrically conductive contact pin according to a preferred first embodiment of the present invention, and FIG. 9F is a sectional view taken along line A-A′ of FIG. 9E.

FIG. 9G is a plan view illustrating a state in which a functional layer is partially provided among a plurality of slits in an electrically conductive contact pin according to a preferred first embodiment of the present invention, and FIG. 9H is a sectional view taken along line A-A′ of FIG. 9G.

FIGS. 10A to 10E are plan views illustrating a state in which a functional layer is partially provided in the length direction of the slit in an electrically conductive contact pin according to a preferred first embodiment of the present invention.

FIG. 11A is a plan view illustrating a state in which a functional layer is partially provided in the thickness direction of the slit in an electrically conductive contact pin according to a preferred first embodiment of the present invention, and FIG. 11B is a sectional view taken along line A-A′ of FIG. 11A.

FIG. 12A is a plan view illustrating a state in which a functional layer is partially provided in the thickness direction of the slit in an electrically conductive contact pin according to a preferred first embodiment of the present invention, and FIG. 12B is a sectional view taken along line A-A′ of FIG. 12A.

FIG. 13A is a plan view of an electrically conductive contact pin before a functional layer is provided in the slit, in an electrically conductive contact pin according to a preferred second embodiment of the present invention, and FIG. 13B is a sectional view taken along line A-A′ of FIG. 13C.

FIG. 14A is a plan view of an electrically conductive contact pin according to a preferred second embodiment of the present invention, and FIG. 14B is a sectional view taken along line A-A′ of FIG. 14A.

FIG. 15A is a plan view of an electrically conductive contact pin before a functional layer is provided in the slit, in an electrically conductive contact pin according to a preferred third embodiment of the present invention, and FIG. 15B is a sectional view taken along line A-A′ of FIG. 15C.

FIG. 16A is a plan view of an electrically conductive contact pin according to a preferred third embodiment of the present invention, and FIG. 16B is a sectional view taken along line A-A′ of FIG. 16A.

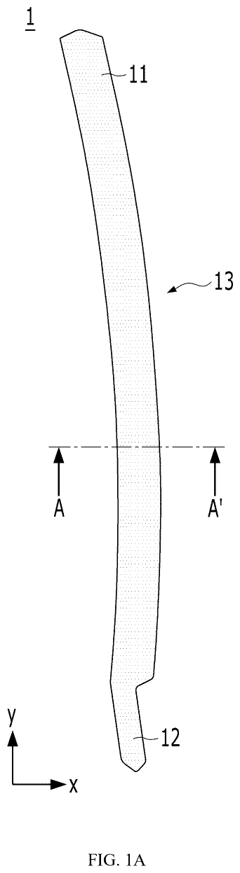

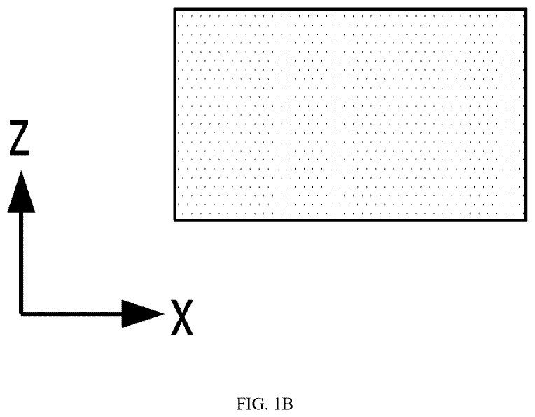

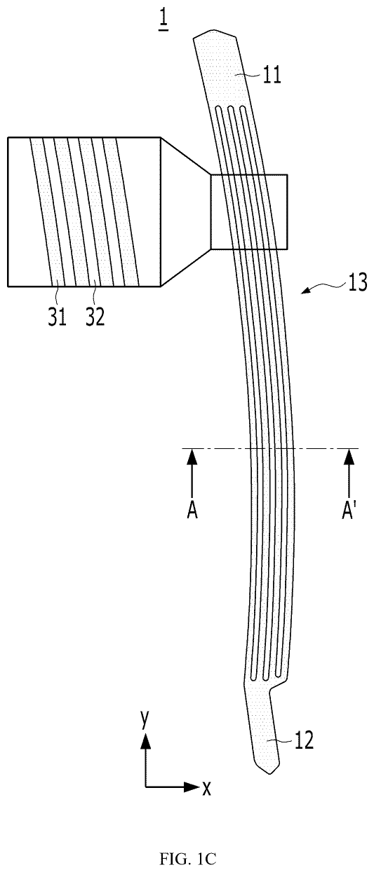

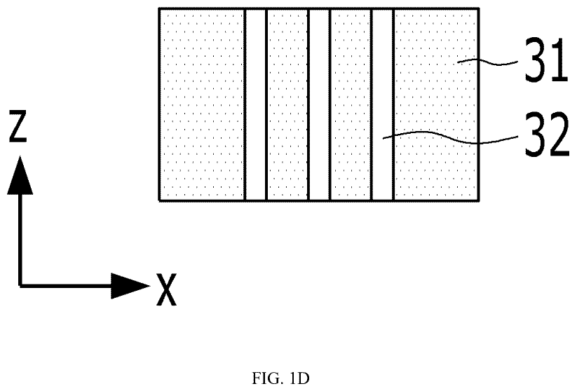

### DETAILED DESCRIPTION OF THE EMBODIMENTS

The following content merely illustrates the principles of the invention. Therefore, those skilled in the art can implement the principles of the invention and invent various devices included in the concept and scope of the invention, even if they are not explicitly described or shown in this specification. Furthermore, all conditional terms and embodiments listed in this specification are, in principle, explicitly intended only for the purpose of understanding the concept of the invention and should not be understood as being limited to the specifically listed embodiments and conditions.

The aforementioned objectives, features, and advantages will become more apparent through the following detailed description in connection with the accompanying drawings, thereby enabling those skilled in the art to easily implement the technical idea of the invention.

The embodiments described in this specification will be explained with reference to ideal exemplary cross-sectional views and/or perspective views of the invention. The thicknesses of the films and regions shown in these drawings are exaggerated for effective explanation of the technical content. The shapes of the illustrations may be modified due to manufacturing techniques and/or tolerances. Additionally, the number of molded objects shown in the drawings is illustrative, and only a portion is depicted in the drawings. Therefore, the embodiments of the present invention are not limited to the specific forms shown but also include variations in shape generated by the manufacturing process.

Hereinafter, the preferred embodiments of the present invention will be described in detail with reference to the accompanying drawings.

An electrically conductive contact pin 100a to 100c according to a preferred embodiment of the present invention is provided in a testing device and is used to transmit electrical signals by electrically and physically contacting the object to be tested. The testing device may be a testing device used in a semiconductor manufacturing process, such as a probe card or a test socket. In this case, the object to be tested may be a semiconductor device in the state of a semiconductor wafer or a semiconductor package.

The testing device comprises an electrically conductive contact pin 100a to 100c and a guide housing having a through-hole for accommodating the electrically conductive contact pin 100a to 100c.

The electrically conductive contact pin 100a to 100c may be a probe pin provided in a probe card or a socket pin provided in a test socket. The electrically conductive contact pin 100a according to the first embodiment and the electrically conductive contact pin 100b according to the second embodiment may be probe pins, and the electrically conductive contact pin 100c according to the third embodiment may be a socket pin. However, the application field of the electrically conductive contact pin 100a to 100c according to the preferred embodiment of the present invention is not limited thereto and includes all pins used to apply electricity to determine whether the object to be tested is defective.

In the following description, the width direction of the electrically conductive contact pin 100a to 100c is the ±x direction indicated in the drawings, the length direction is the ±y direction indicated in the drawings, and the thickness direction is the ±z direction indicated in the drawings.

The electrically conductive contact pin 100a to 100c has an overall length dimension in the length direction (±y direction), an overall thickness dimension in the thickness direction (±z direction) perpendicular to the length direction, and an overall width dimension in the width direction (±x direction) perpendicular to the length direction.

In describing various embodiments below, components performing the same function will be given the same name and reference number for convenience, even if the embodiments differ. Additionally, the configuration and operation already described in other embodiments will be omitted for convenience.

### Electrically Conductive Contact Pin 100a According to the First Embodiment

The electrically conductive contact pin 100a according to the first embodiment may be a probe pin used in a probe card. More specifically, it may be a vertical probe pin inserted and installed in the guide hole of a guide housing to inspect a semiconductor wafer.

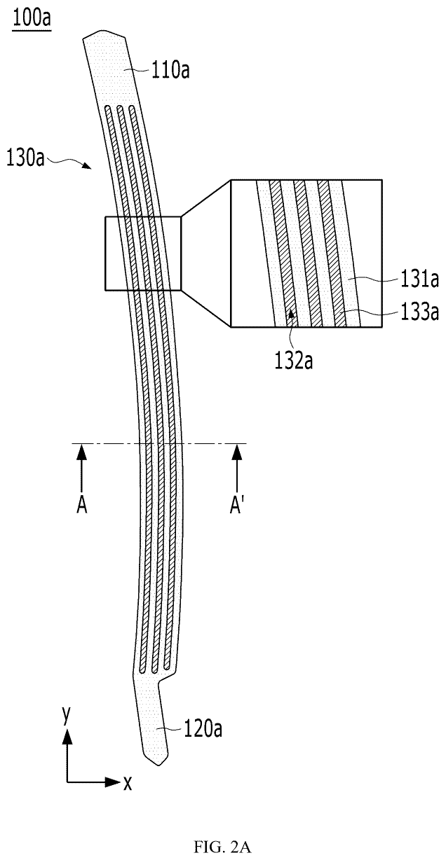

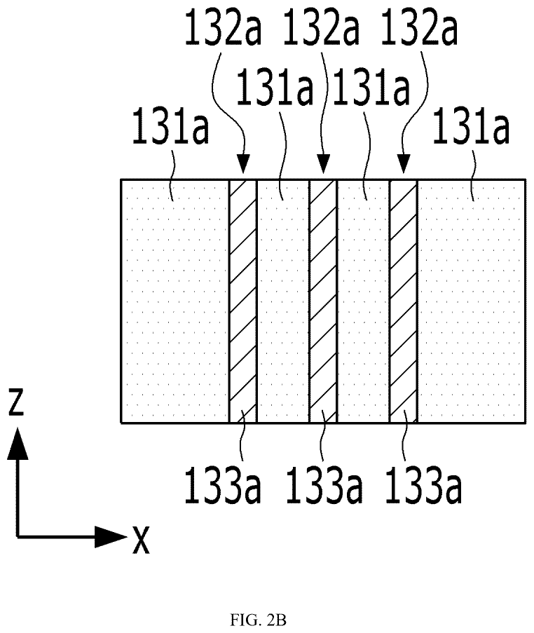

Hereinafter, the electrically conductive contact pin 100a according to the preferred first embodiment of the present invention will be described with reference to FIGS. 2A to 12B.

First, referring to FIGS. 2A and 2B, FIG. 2A is a plan view of the electrically conductive contact pin 100a according to the preferred first embodiment of the present invention, and FIG. 2B is a cross-sectional view taken along line A-A′ of FIG. 2A.

The electrically conductive contact pin 100a comprises a first end region 110a, a second end region 120a, and a body region 130a positioned between the first and second end regions 110a, 120a. The first end region 110a is a region connected to the connection pad of a circuit board, and the second end region 120a is a region connected to the external terminal of a semiconductor wafer. The body region 130a is a region that deforms while varying its curvature in the width direction (±x direction) due to the pressing force applied through both end regions.

The body region 130a includes at least two beam portions 131a. The beam portions 131a are elastically deformed by the pressing force applied to the electrically conductive contact pin 100a. The beam portions 131a are spaced apart from each other by a slit 132a. The beam portions 131a located on both sides of the slit 132a are separated or detached from each other.

The slit 132a is formed to extend in the length direction (±y direction) of the body region 130a. Additionally, a plurality of slits 132a may be provided, spaced apart from each other in the width direction (±x direction). For example, there may be three slits 132a.

A functional layer 133a is provided inside the slit 132a. The beam portions 131a and the functional layer 133a are alternately arranged in the width direction (±x direction). Additionally, the beam portions 131a and the functional layer 133a are arranged parallel to each other.

Each slit 132a has a length in the width direction (±x direction) and a length in the length direction (±y direction). Here, since the length of the slit 132a in the length direction (±y direction) is longer than its length in the width direction (±x direction), the length of the functional layer 133a in the width direction (±x direction) is shorter than its length in the length direction (±y direction).

The beam portions 131a and the functional layer 133a may each be formed of a single metal layer.

In this case, the beam portions 131a are composed of a metal with a higher elastic modulus than the functional layer 133a. For example, the beam portions 131a may be formed of a metal selected from rhodium (Rd), platinum (Pt), iridium (Ir), palladium (Pd), nickel (Ni), manganese (Mn), tungsten (W), phosphorus (P), or alloys thereof, or palladium-cobalt (PdCo) alloy, palladium-nickel (PdNi) alloy, nickel-phosphorus (NiP) alloy, nickel-manganese (NiMn), nickel-cobalt (NiCo), or nickel-tungsten (NiW) alloy.

Additionally, the functional layer 133a is composed of a metal with higher electrical conductivity than the metal constituting the beam portions 131a. For example, the functional layer 133a may be formed of a metal selected from copper (Cu), silver (Ag), gold (Au), or alloys thereof. For instance, the beam portions 131a may be composed of a palladium-cobalt (PdCo) alloy, and the functional layer 133a may be composed of copper (Cu).

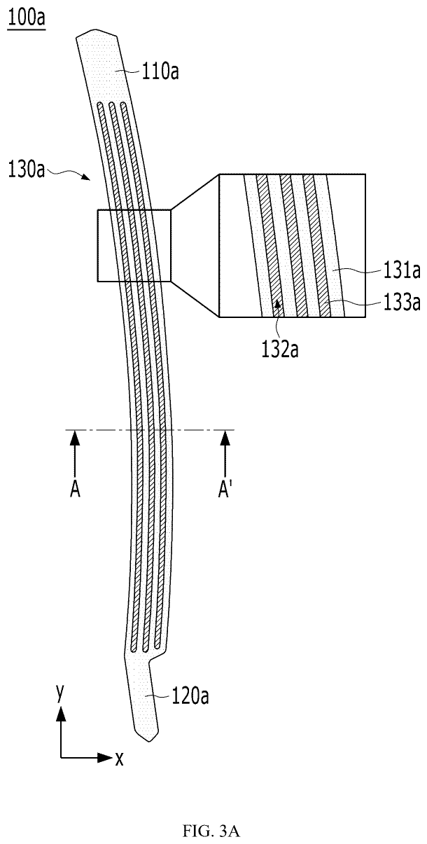

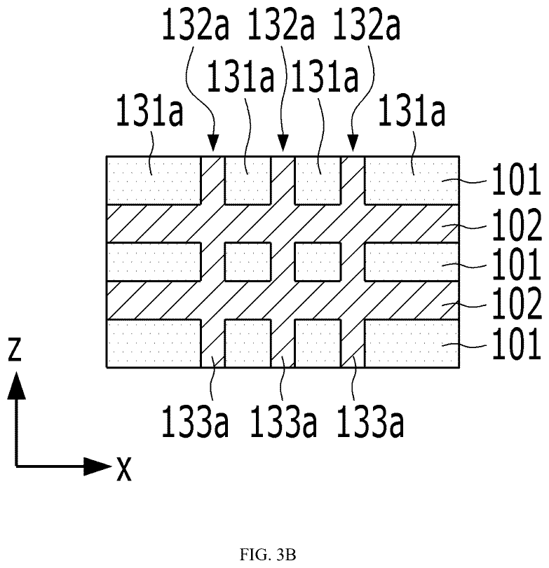

Alternatively, referring to FIGS. 3A and 3B, the beam portions 131a may be provided with a plurality of different metal layers stacked, and the functional layer 133a may be formed of a single metal layer. The beam portions 131a are provided with a plurality of metal layers stacked in the thickness direction (±z direction). The plurality of metal layers include a first metal layer 101 and a second metal layer 102.

The first metal layer 101 is a metal with relatively higher wear resistance or elastic modulus than the second metal layer 102 and is preferably formed of a metal selected from rhodium (Rd), platinum (Pt), iridium (Ir), palladium (Pd), nickel (Ni), manganese (Mn), tungsten (W), phosphorus (P), or alloys thereof, or palladium-cobalt (PdCo) alloy, palladium-nickel (PdNi) alloy, nickel-phosphorus (NiP) alloy, nickel-manganese (NiMn), nickel-cobalt (NiCo), or nickel-tungsten (NiW) alloy. The second metal layer 102 is a metal with relatively higher electrical conductivity than the first metal layer 101 and is preferably formed of a metal selected from copper (Cu), silver (Ag), gold (Au), or alloys thereof.

The first metal layer 101 constituting the beam portions 131a is provided on the lower and upper surfaces of the electrically conductive contact pin 100a in the thickness direction (±z direction), and the second metal layer 102 is provided between the first metal layers 101. For example, the beam portions 131a may be alternately stacked in the order of the first metal layer 101, the second metal layer 102, and the first metal layer 101, and the number of stacked layers may be three or more.

The functional layer 133a may be formed of a metal selected from copper (Cu), silver (Ag), gold (Au), or alloys thereof.

The second metal layer 102 constituting the beam portions 131a and the functional layer 133a may be made of the same material. For example, the second metal layer 102 and the functional layer 133a may be formed of the same metal selected from copper (Cu), silver (Ag), or gold (Au). For instance, the beam portions 131a may be composed of palladium-cobalt (PdCo) alloy-copper (Cu)-palladium-cobalt (PdCo) alloy-copper (Cu)-palladium-cobalt (PdCo) alloy in sequence, and the functional layer 133a may be composed of copper (Cu).

Alternatively, the second metal layer 102 constituting the beam portions 131a and the functional layer 133a may be made of different materials. For example, when the second metal layer 102 is one metal selected from copper (Cu), silver (Ag), or gold (Au), the functional layer 133a may be formed of a different material from the second metal layer 102 and may be formed of another metal selected from copper (Cu), silver (Ag), or gold (Au). For instance, the beam portions 131a may be composed of palladium-cobalt (PdCo) alloy-copper (Cu)-palladium-cobalt (PdCo) alloy-copper (Cu)-palladium-cobalt (PdCo) alloy in sequence, and the functional layer 133a may be composed of gold (Au).

The first end region 110a and/or the second end region 120a may be formed by stacking a plurality of metal layers, including the first metal layer 101 and the second metal layer 102, considering the current carrying capacity (CCC). In this case, the first end region 110a and/or the second end region 120a may be configured by integrally extending the first metal layer 101 and the second metal layer 102 constituting the beam portions 131a.

Alternatively, the first end region 110a and/or the second end region 120a may be formed of a metal material different from the beam portions 131a, considering wear resistance. For example, the first end region 110a and/or the second end region 120a may be formed of a single material selected from rhodium (Rd), platinum (Pt), iridium (Ir), palladium (Pd), nickel (Ni), manganese (Mn), tungsten (W), phosphorus (P), or alloys thereof, or palladium-cobalt (PdCo) alloy, palladium-nickel (PdNi) alloy, nickel-phosphorus (NiP) alloy, nickel-manganese (NiMn), nickel-cobalt (NiCo), or nickel-tungsten (NiW) alloy.

The functional layer 133a has an electrical conductivity greater than that of the beam portions 131a. Regardless of whether the beam portions 131a are composed of a single metal layer or a plurality of metal layers including the first and second metal layers 101, 102, the functional layer 133a has an electrical conductivity greater than that of the beam portions 131a. Here, when the beam portions 131a are composed of a plurality of metal layers, the electrical conductivity of the beam portions 131a refers to the average electrical conductivity of the plurality of metal layers.

The functional layer 133a has an elastic modulus smaller than that of the beam portions 131a. Regardless of whether the beam portions 131a are composed of a single metal layer or a plurality of metal layers including the first and second metal layers 101, 102, the functional layer 133a has an elastic modulus smaller than that of the beam portions 131a. Here, when the beam portions 131a are composed of a plurality of metal layers, the elastic modulus of the beam portions 131a refers to the average elastic modulus of the plurality of metal layers.

The functional layer 133a contacts a plurality of metal layers provided in the thickness direction (±z direction) of the beam portions 131a at the bonding surface with the beam portions 131a. The beam portions 131a are configured by alternately stacking the first metal layer 101 and the second metal layer 102. Through this, the second metal layers 102 of the beam portions 131a, which have high electrical conductivity, are connected to the functional layer 133a, which also has high electrical conductivity. In a structure without the functional layer 133a, the second metal layers 102 constituting the beam portions 131a are disconnected in the thickness direction (±z direction) by the first metal layer 101, which has relatively low electrical conductivity. However, according to the embodiment of the present invention, the second metal layers 102 constituting the beam portions 131a are connected to each other by the functional layer 133a, resulting in a structure where the second metal layers 102 are electrically connected. This improves the current carrying capacity (CCC) of the electrically conductive contact pin 100a.

On the other hand, if the inside of the slit 132a is left empty, stress may concentrate at both ends of the slit 132a in the length direction (±y direction) due to the abrupt change in cross-sectional area, causing local failure of the beam portions 131a. However, according to the embodiment of the present invention, by providing the functional layer 133a inside the slit 132a, the abrupt increase in stress at both ends of the slit 132a is prevented, thereby preventing local failure of the beam portions 131a.

Meanwhile, if the functional layer 133a is provided inside the slit 132a, the elastic modulus may increase compared to a structure without the functional layer 133a inside the slit 132a. However, by forming the beam portions 131a not as a single metal layer but as multilayer plating with the first and second metal layers 101, 102, the increase in elastic modulus is suppressed through material changes, thereby preventing an increase in contact pressure.

As described above, the present invention reduces the elastic modulus by multilayer plating the beam portions 131a with the first and second metal layers 101, 102 to prevent an increase in contact pressure, while providing the functional layer 133a inside the slit 132a to prevent local failure of the beam portions 131a. Furthermore, by forming the functional layer 133a of at least one metal with high electrical conductivity, such as copper (Cu), silver (Ag), or gold (Au), the current carrying capacity (CCC) is improved.

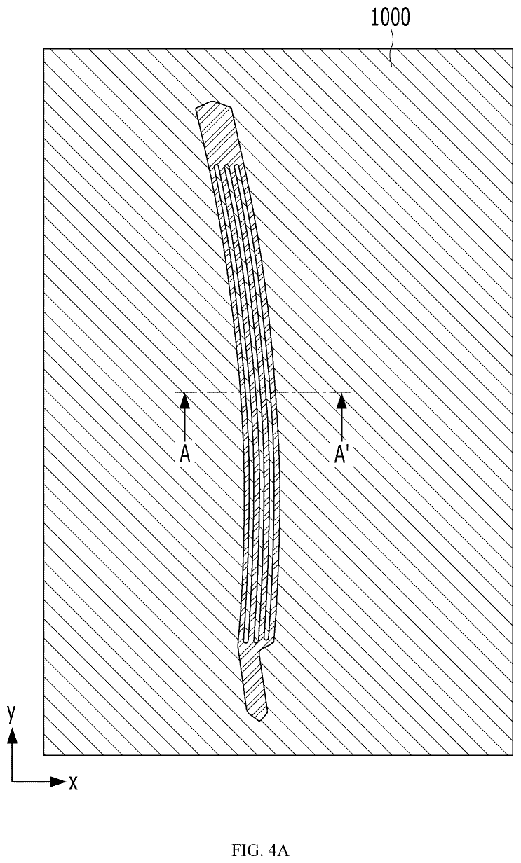

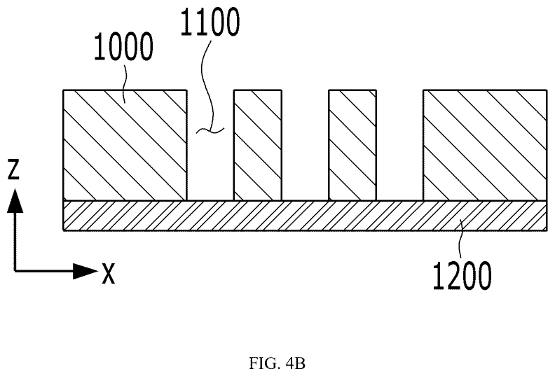

Next, the manufacturing method of the electrically conductive contact pin 100a according to the preferred first embodiment of the present invention will be described with reference to FIGS. 4A to 7B.

First, a first internal space 1100 is formed in the mold 1000. FIG. 4A is a plan view showing the state where the first internal space 1100 is formed in the mold 1000, and FIG. 4B is a cross-sectional view taken along line A-A′ of FIG. 4A.

The mold 1000 may be composed of anodized film, photoresist, silicon wafer, or similar materials. However, preferably, the mold 1000 may be composed of anodized film. The anodized film refers to a film formed by anodizing a base metal, and pores refer to holes formed during the process of forming the anodized film by anodizing the base metal. For example, when the base metal is aluminum (Al) or an aluminum alloy, anodizing the base metal forms an anodized film of aluminum oxide (Al₂O₃) material on the surface of the base metal. However, the base metal is not limited thereto and may include Ta, Nb, Ti, Zr, Hf, Zn, W, Sb, or alloys thereof. The anodized film formed as described above is divided into a barrier layer without vertically formed pores inside and a porous layer with vertically formed pores inside. When the base metal with an anodized film having a barrier layer and a porous layer on its surface is removed, only the anodized film of aluminum oxide (Al₂O₃) material remains. The anodized film may be formed in a structure where the barrier layer formed during anodizing is removed, and the pores penetrate vertically, or in a structure where the barrier layer formed during anodizing remains, sealing one end of the pores.

The anodized film has a thermal expansion coefficient of 2˜3 ppm/° C. As a result, it undergoes little thermal deformation when exposed to high-temperature environments. Therefore, even in high-temperature environments during the manufacturing process of the electrically conductive contact pin 100a, precise electrically conductive contact pins 100a can be manufactured without thermal deformation.

Conventionally, molds for manufacturing electrically conductive contact pins were made using photoresist (PR) instead of anodized film. Repeating the process of spraying and hardening the liquid component of the photosensitive solution created layers in units of 30 μm in the thickness direction (±z direction). Even after completing the electrically conductive contact pin, nodes formed at the layer transitions, like bamboo joints, made it prone to deformation. There were also limitations in building tall molds and achieving precise patterning. However, the preferred embodiment of the present invention can solve these problems by using a mold 1000 made of anodized film material. Since the anodized film is already in a solid state, it allows precise patterning through etching. Additionally, due to the solid nature of the anodized film, the mold 1000 can be formed without layers in the thickness direction (±z direction) in units of 100 μm. As a result, unlike the conventional method, the completed electrically conductive contact pin 100a has no nodes in the thickness direction (±z direction), preventing deformation even after use. The electrically conductive contact pin 100a according to the preferred embodiment of the present invention also has higher electrical conductivity than conventional pins and can be used without signal loss in high-frequency bands of 100 GHz or more.

Thus, the electrically conductive contact pin 100a according to the preferred embodiment of the present invention can exhibit the effects of precision in shape and implementation of fine shapes, which were limited in the photoresist mold, by being manufactured using a mold 1000 made of anodized film material instead of a photoresist mold. Additionally, while the conventional photoresist mold could produce electrically conductive contact pins with a thickness of about 40 μm, using a mold 1000 made of anodized film material allows the production of electrically conductive contact pins 100a with a thickness of 100 μm or more and 200 μm or less.

A seed layer 1200 for electroplating is provided on the lower surface of the mold 1000. The seed layer 1200 may be provided on the lower surface of the mold 1000 before forming the first internal space 1100 in the mold 1000. Meanwhile, a support substrate (not shown) may be formed below the mold 1000 to improve the handling of the mold 1000. In this case, the seed layer 1200 may be formed on the upper surface of the support substrate, and the mold 1000 with the first internal space 1100 formed may be bonded to the support substrate for use. The seed layer 1200 may be formed of, for example, copper (Cu) material and may be formed by a deposition method.

The first internal space 1100 may be formed by wet etching the mold 1000 made of anodized film material. To this end, the upper surface of the mold 1000 is provided with photoresist, which is then patterned, and the anodized film in the patterned and opened area reacts with the etching solution to form the first internal space 1100.

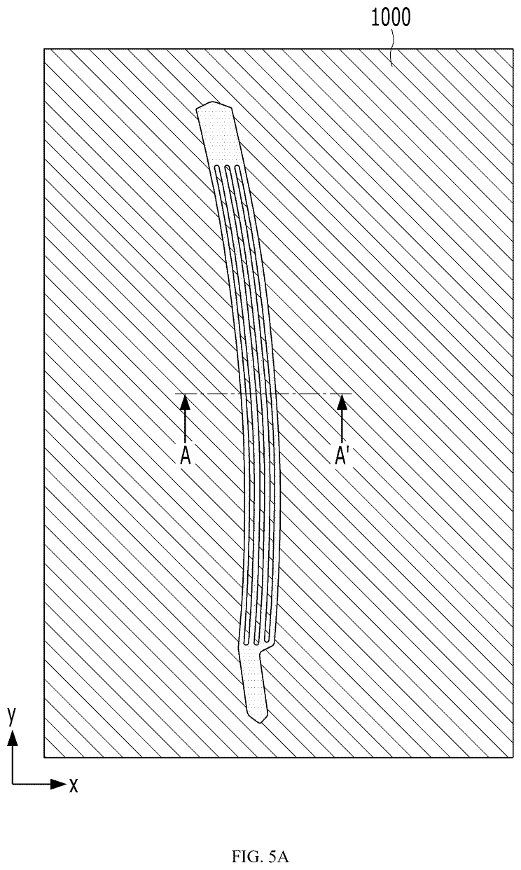

Next, an electroplating process is performed in the first internal space 1100 of the mold 1000 to form the beam portions 131a of the first end region 110a, the second end region 120a, and the body region 130a. FIG. 5A is a plan view showing the state where multilayer plating is performed in the first internal space 1100, and FIG. 5B is a cross-sectional view taken along line A-A′ of FIG. 5A.

Using the seed layer 1200, an electroplating process is performed to form a metal layer in the first internal space 1100.

Since the metal layer grows in the thickness direction (±z direction) of the mold 1000, the shape of each cross-section in the thickness direction (±z direction) of the mold 1000 is the same, and a plurality of metal layers are stacked in the thickness direction (±z direction) of the mold 1000. The plurality of metal layers include a first metal layer 101 and a second metal layer 102. The first metal layer 101 is a metal with relatively higher wear resistance than the second metal layer 102 and includes rhodium (Rd), platinum (Pt), iridium (Ir), palladium (Pd), or alloys thereof, or palladium-cobalt (PdCo) alloy, palladium-nickel (PdNi) alloy, nickel-phosphorus (NiP) alloy, nickel-manganese (NiMn), nickel-cobalt (NiCo), or nickel-tungsten (NiW) alloy. The second metal layer 102 is a metal with relatively higher electrical conductivity than the first metal layer 101 and includes copper (Cu), silver (Ag), gold (Au), or alloys thereof.

The first metal layer 101 is provided on the lower and upper surfaces of the electrically conductive contact pin 100a in the thickness direction (±z direction), and the second metal layer 102 is provided between the first metal layers 101. For example, the electrically conductive contact pin 100a may be alternately stacked in the order of the first metal layer 101, the second metal layer 102, and the first metal layer 101, and the number of stacked layers may be three or more.

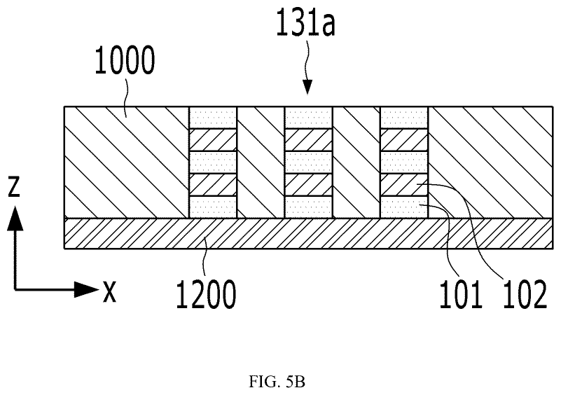

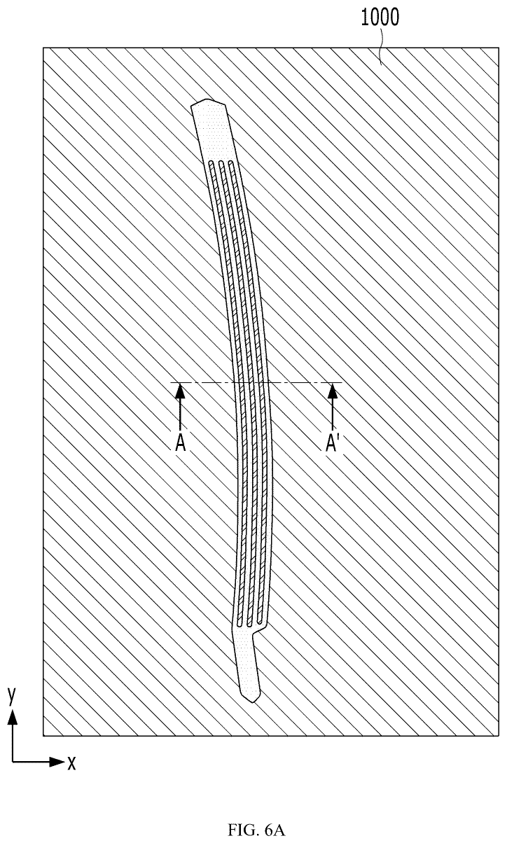

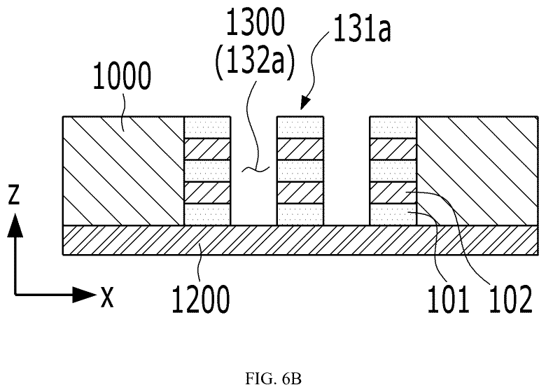

Next, a second internal space 1300 is formed in the mold 1000. FIG. 6A is a plan view showing the state where the second internal space 1300 is formed by partially removing the mold 1000, and FIG. 6B is a cross-sectional view taken along line A-A′ of FIG. 6A.

The second internal space 1300 is formed by wet etching and removing the anodized film surrounded by adjacent beam portions 131a, the first end region 110a, and the second end region 120a. For this purpose, a photoresist is provided on the upper surface of the mold 1000, patterned, and then the anodized film in the patterned and opened area reacts with the etching solution to form the second internal space 1300. As the anodized film is removed, the second internal space 1300 is formed in a sealed shape by the adjacent beam portions 131a, the first end region 110a, and the second end region 120a. The second internal space 1300 becomes the slit 132a.

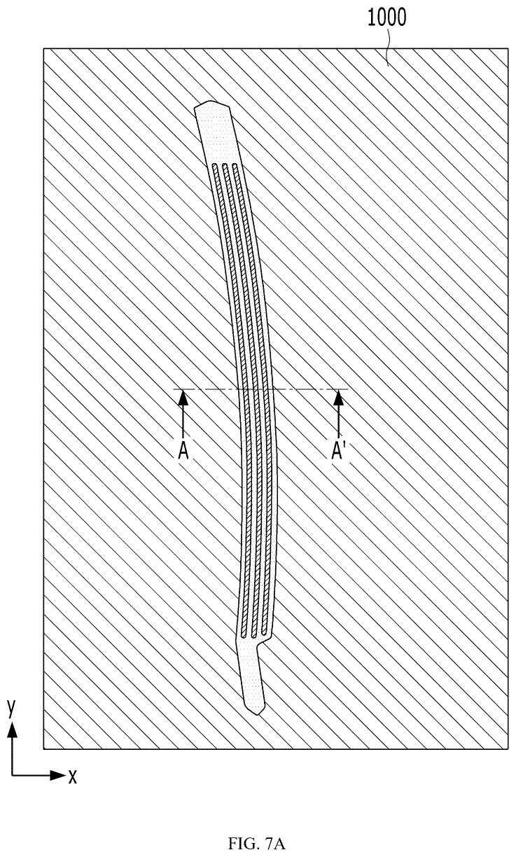

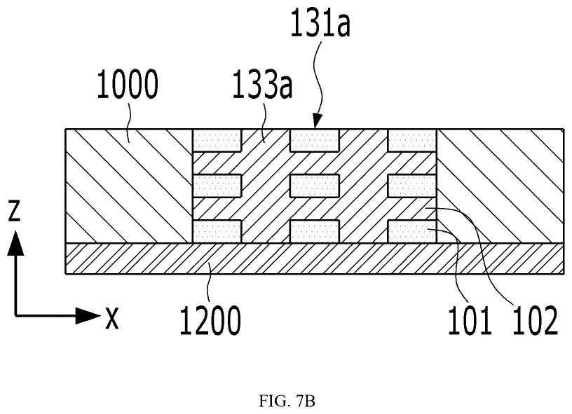

Next, an electroplating process is performed in the second internal space 1300 to form the functional layer 133a. FIG. 7A is a plan view showing the state in which the functional layer 133a is formed in the second internal space 1300, and FIG. 7B is a cross-sectional view taken along line A-A′ of FIG. 7A.

Using the seed layer 1200 and the metal layer formed around the second internal space 1300, an electroplating process is performed to form the functional layer in the second internal space 1300.

The functional layer 133a may be formed of a metal selected from copper (Cu), silver (Ag), gold (Au), or alloys thereof. The second metal layer 102 constituting the beam portion 131a and the functional layer 133a may be made of the same metal material. For example, the second metal layer 102 and the functional layer 133a may be formed of the same metal selected from copper (Cu), silver (Ag), or gold (Au). Alternatively, the second metal layer 102 constituting the beam portion 131a and the functional layer 133a may be made of different metal materials. For example, when the second metal layer 102 is one metal selected from copper (Cu), silver (Ag), or gold (Au), the functional layer 133a may be formed of a different material from the second metal layer 102 and another metal selected from copper (Cu), silver (Ag), or gold (Au).

Meanwhile, after the plating process is completed, the metal layer completed by the plating process can be densified by applying pressure after heating to a high temperature. When a photoresist material is used as the mold, the photoresist remains around the metal layer after the plating process is completed, so the process of applying pressure after heating to a high temperature cannot be performed. On the other hand, according to a preferred embodiment of the present invention, since the mold 1000 made of an anodized film material is provided around the metal layer completed by the plating process, it is possible to densify the plating layer while minimizing deformation due to the low thermal expansion coefficient of the anodized film even when heated to a high temperature. Therefore, it is possible to obtain a more densified plating layer compared to the technology using a photoresist as a mold.

After the electroplating process is completed, a process of removing the mold 1000 and the seed layer 1200 is performed. When the mold 1000 is made of an anodized film material, the mold 1000 is removed using a solution that selectively reacts with the anodized film material. Additionally, when the seed layer 1200 is made of copper (Cu), the seed layer 1200 is removed using a solution that selectively reacts with copper (Cu).

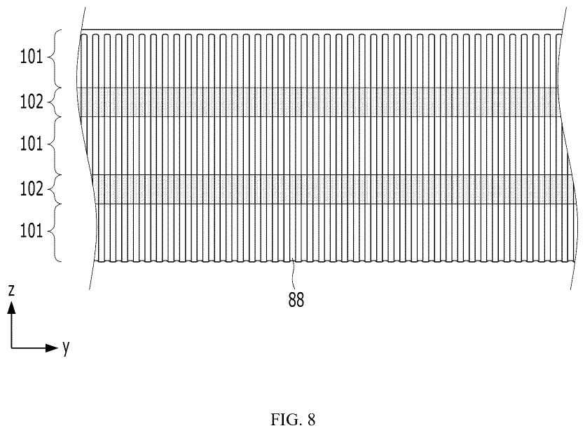

Referring to FIG. 8, the electrically conductive contact pin 100a according to preferred embodiments of the present invention includes a plurality of micro trenches 88 on its side surface. The micro trenches 88 are formed to extend longitudinally in the thickness direction (±z direction) of the electrically conductive contact pin 100a from the side surface of the electrically conductive contact pin 100a. Here, the thickness direction (±z direction) of the electrically conductive contact pin 100a refers to the direction in which the metal filler grows during electroplating.

The micro trenches 88 have a depth in the range of 20 nm to 1 μm and a width in the range of 20 nm to 1 μm. Here, since the micro trenches 88 are caused by the pore holes formed during the manufacturing of the anodized film mold, the width and depth of the micro trenches 88 have values within the range of the pore hole diameter of the anodized film mold 1000. Meanwhile, during the process of forming the first internal space 1100 in the anodized film mold 1000, some of the pore holes of the anodized film mold 1000 may be crushed by the etching solution, and micro trenches 88 with a depth greater than the range of the pore hole diameter formed during anodization may be partially formed.

The anodized film mold 1000 includes numerous pore holes, and by etching at least a portion of such an anodized film mold 1000, the first internal space 1100 is formed. Since metal fillers are formed by electroplating inside the first internal space 1100, the side surface of the electrically conductive contact pin 100a is provided with micro trenches 88 formed in contact with the pore holes of the anodized film mold 1000.

The above-described micro trenches 88 have the effect of increasing the surface area on the side surface of the electrically conductive contact pin 100a. Through the configuration of the micro trenches 88 formed on the side surface of the electrically conductive contact pin 100a, heat generated in the electrically conductive contact pin 100a can be quickly dissipated, thereby suppressing the temperature rise of the electrically conductive contact pin 100a. Additionally, through the configuration of the micro trenches 88 formed on the side surface of the electrically conductive contact pin 100a, the torsional resistance capability during deformation of the electrically conductive contact pin 100a can be improved.

Furthermore, the micro trenches 88 are also formed on the side surface of the beam portion 131a when forming the second internal space 1300 or the slit 132a. In other words, the micro trenches 88 are provided on the inner wall of the slit 132a. Therefore, due to the micro trenches 88 formed on the inner wall of the slit 132a, the functional layer 133a formed in the second internal space 1300 is more firmly bonded to the beam portion 131a.

The functional layer 133a may be provided entirely in the slit 132a. That the functional layer 133a is provided entirely in the slit 132a means that the functional layer 133a is configured to completely fill the space formed by the slit 132a.

The functional layer 133a may be provided partially in the slit 132a. That the functional layer 133a is provided partially in the slit 132a means that the functional layer 133a is configured to partially fill the space formed by the slit 132a.

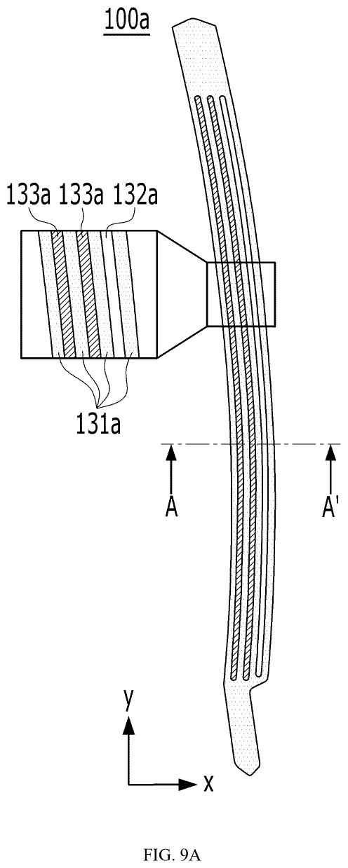

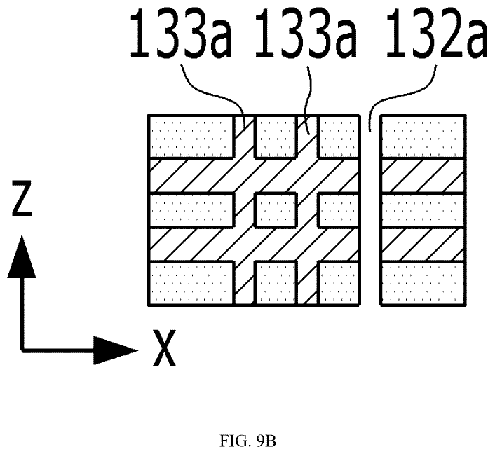

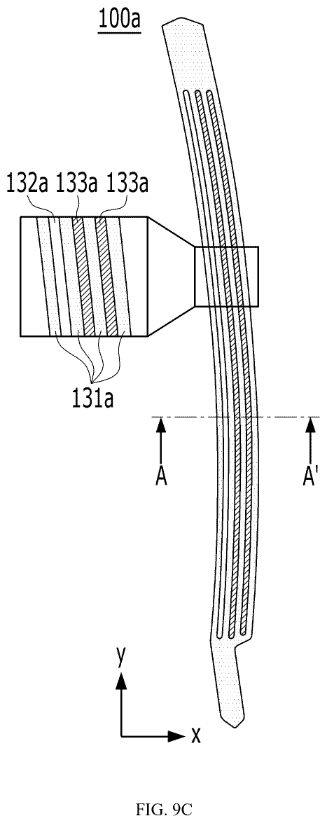

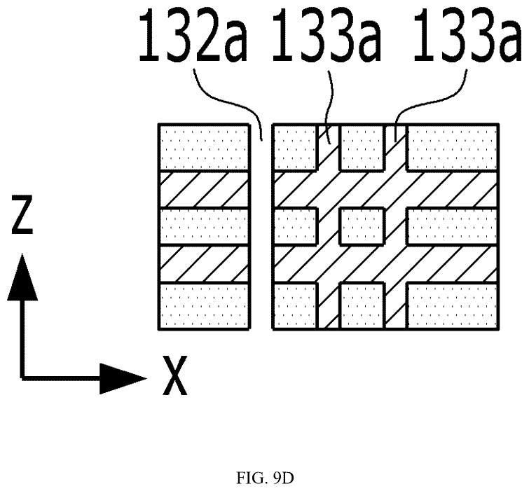

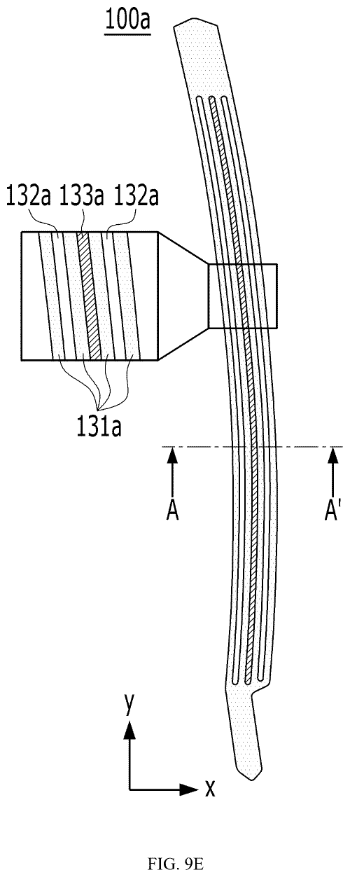

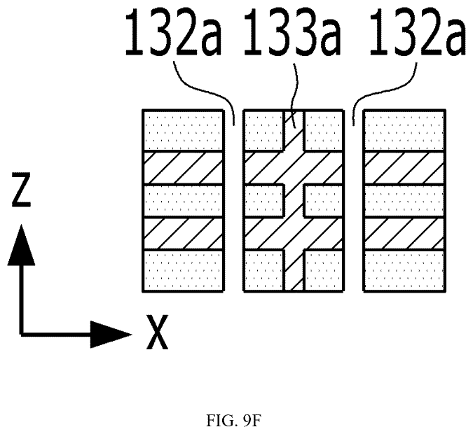

The functional layer 133a may be provided partially among a plurality of slits 132a. FIGS. 9A to 9H illustrate configurations in which the functional layer 133a is partially provided among a plurality of slits 132a in the electrically conductive contact pin 100a according to a preferred first embodiment of the present invention. In FIGS. 9A to 9H, three slits 132a are shown, but the invention is not limited thereto.

Referring to FIGS. 9A and 9B, three slits 132a are provided, and the functional layer 133a is provided only in the left two slits 132a among the three slits 132a, and not in the right one slit 132a.

Referring to FIGS. 9C and 9D, three slits 132a are provided, and the functional layer 133a is provided only in the right two slits 132a among the three slits 132a, and not in the left one slit 132a.

Referring to FIGS. 9E and 9F, three slits 132a are provided, and the functional layer 133a is provided only in the middle one slit 132a among the three slits 132a, and not in the left and right two slits 132a.

Referring to FIGS. 9G and 9H, three slits 132a are provided, and the functional layer 133a is provided only in the left and right two slits 132a among the three slits 132a, and not in the middle one slit 132a.

As shown in FIGS. 9A to 9H, according to the configuration in which the functional layer 133a is partially provided among a plurality of slits 132a, in addition to the effects of the functional layer 133a configuration, it is possible to appropriately select the contact pressure and current carrying capacity (CCC) in relation to the length of the electrically conductive contact pin 100a and the inspection device. Additionally, depending on whether the electrically conductive contact pin 100a is a signal pin, a ground pin, or a power pin, the functional layer 133a can be partially provided among a plurality of slits 132a.

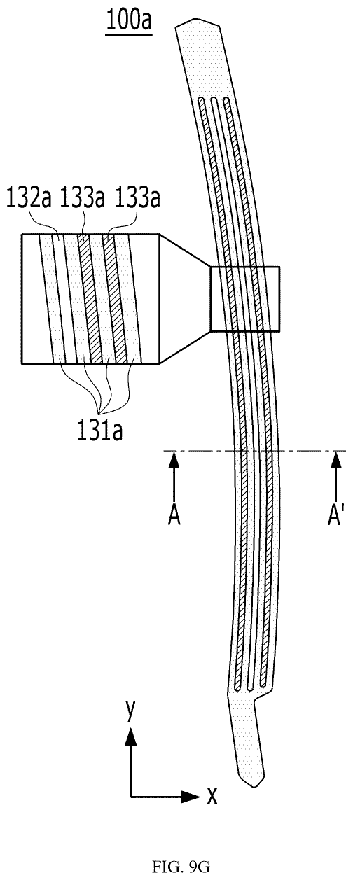

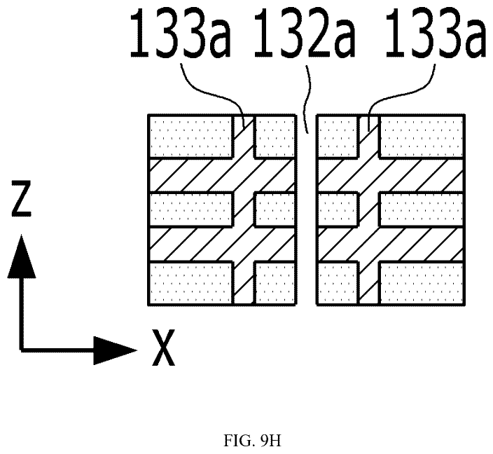

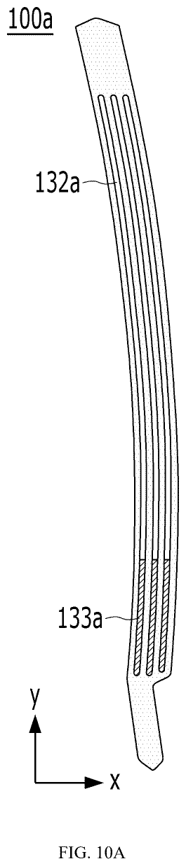

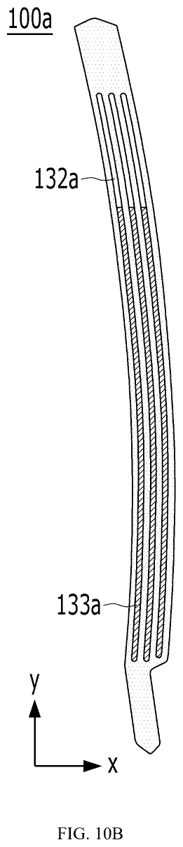

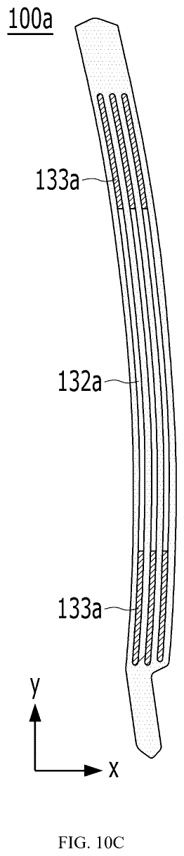

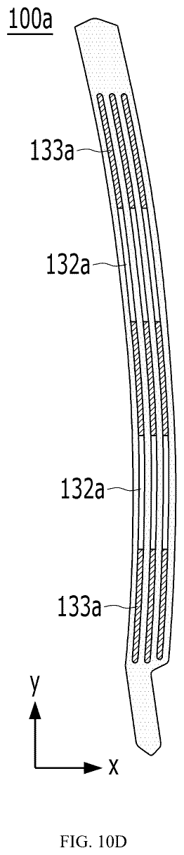

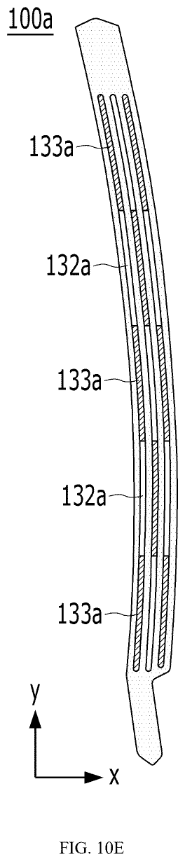

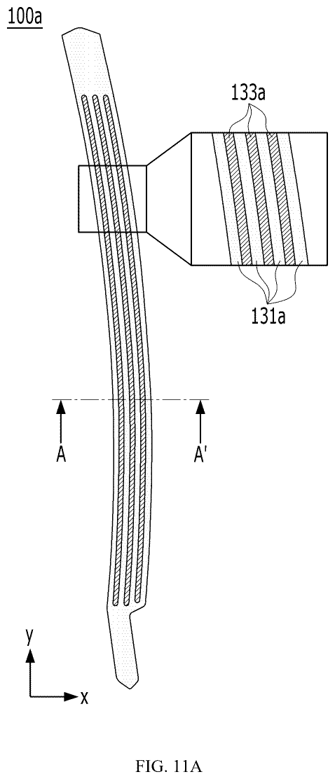

The functional layer 133a may be provided partially in the length direction of the slit 132a. FIGS. 10A to 10E are plan views showing a configuration in which the functional layer 133a is partially provided in the length direction of the slit 132a in the electrically conductive contact pin 100a according to a preferred first embodiment of the present invention.

Referring to FIG. 10A, three slits 132a are provided, and the functional layer 133a is provided only in the lower side space in the length direction (±y direction) of the slit 132a in each slit 132a, and not in the remaining space.

Referring to FIG. 10B, three slits 132a are provided, and the functional layer 133a is provided only in the remaining space, and not in the upper side space in the length direction (±y direction) of the slit 132a in each slit 132a.

Referring to FIG. 10C, three slits 132a are provided, and the functional layer 133a is provided only in the upper and lower side spaces in the length direction (±y direction) of the slit 132a in each slit 132a, and not in the remaining space.

Referring to FIG. 10D, three slits 132a are provided, and the functional layer 133a is provided only in the upper side, lower side, and central side spaces in the length direction (±y direction) of the slit 132a in each slit 132a, and not in the spaces between the upper side and central side or between the lower side and central side.

Referring to FIG. 10E, three slits 132a are provided. The functional layer 133a is partially provided in the length direction (±y direction) of the slit 132a in each slit 132a, and the functional layer 133a and the empty space are arranged in a zigzag pattern.

As shown in FIGS. 10A to 10E, according to the configuration in which the functional layer 133a is partially provided in the length direction (±y direction) of the slit 132a in the electrically conductive contact pin 100a, in addition to the effects of the functional layer 133a configuration, it is possible to minimize fatigue failure of the electrically conductive contact pin 100a by adjusting the degree of deformation in the length direction (±y direction).

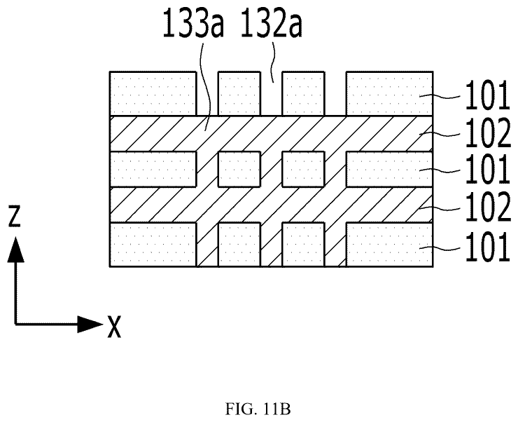

The functional layer 133a may be provided partially in the thickness direction (±z direction) of the slit 132a. FIG. 11A is a plan view showing a configuration in which the functional layer 133a is partially provided in the thickness direction (±z direction) of the slit 132a in the electrically conductive contact pin 100a according to a preferred first embodiment of the present invention, and FIG. 11B is a cross-sectional view taken along line A-A′ of FIG. 11A.

Referring to FIGS. 11A and 11B, the functional layer 133a is formed in such a way that the internal space of the slit 132a is not entirely filled in the thickness direction (±z direction), and a part of the internal space of the slit 132a remains empty in the thickness direction (±z direction). The functional layer 133a is not provided in the upper space in the thickness direction (±z direction) of the slit 132a, but is provided only in the remaining space.

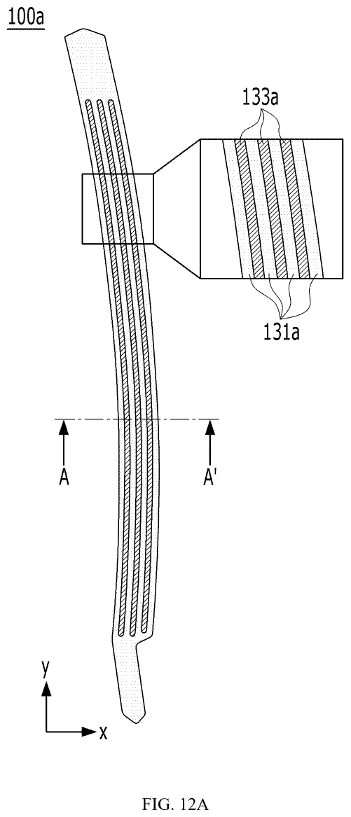

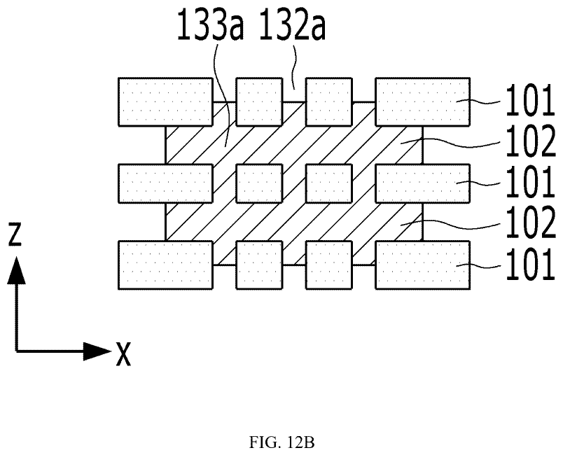

FIG. 12A is a plan view showing that a functional layer 133a is partially provided in the thickness direction (±z direction) of the slit 132a in the electrically conductive contact pin 100a according to the first preferred embodiment of the present invention, and FIG. 12B is a cross-sectional view taken along line A-A′ of FIG. 12A.

Referring to FIGS. 12A and 12B, the functional layer 133a is not provided in the upper and lower spaces in the thickness direction (±z direction) of the slit 132a but is provided only in the remaining space. In addition, the side surface of the portion corresponding to the second metal layer 102 among the metal layers constituting the beam portion 131a may be positioned inward relative to the side surface of the portion corresponding to the first metal layer 101. Through this, only the first metal layer 101 protrudes and is exposed on the surface of the electrically conductive contact pin 100a. Therefore, when the electrically conductive contact pin 100a slides in contact with a guide housing (not shown) during the overdrive process, the problem of wear of the second metal layer 102, which has relatively low wear resistance, can be prevented.

### Electrically Conductive Contact Pin 100b According to the Second Embodiment

The electrically conductive contact pin 100b according to the second embodiment may be a probe pin used in a probe card. More specifically, it may be a cantilever-type probe pin for inspecting a semiconductor wafer.

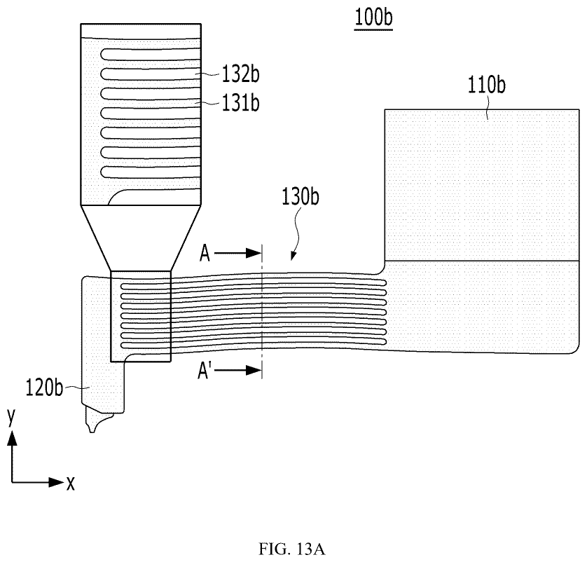

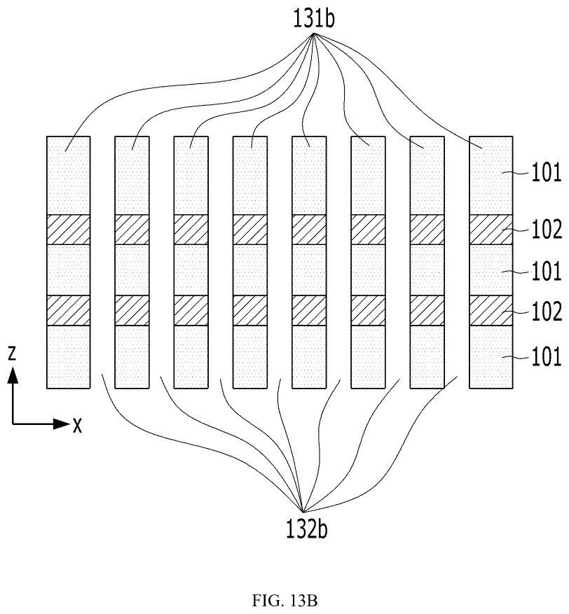

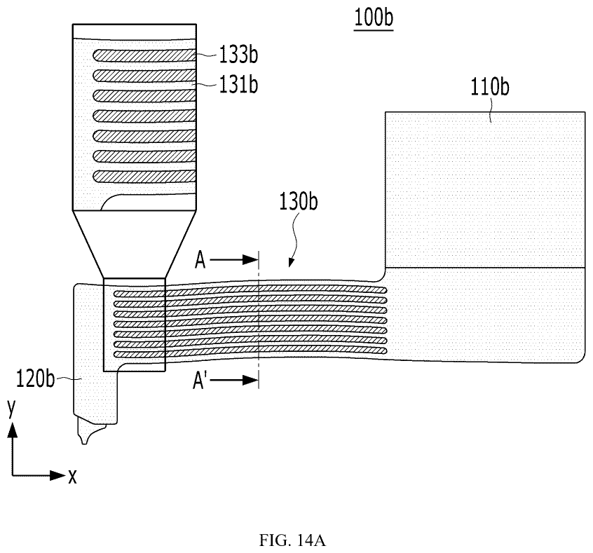

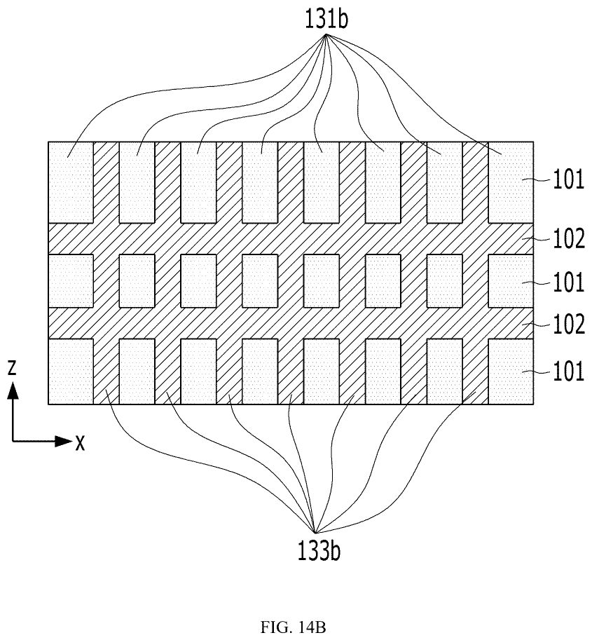

Hereinafter, the electrically conductive contact pin 100b according to the second preferred embodiment of the present invention will be described with reference to FIGS. 13A and 14B. FIG. 13A is a plan view of the electrically conductive contact pin 100b before the functional layer 133b is provided in the slit 132b in the electrically conductive contact pin 100b according to the second preferred embodiment of the present invention, and FIG. 13B is a cross-sectional view taken along line A-A′ of FIG. 13C. FIG. 14A is a plan view of the electrically conductive contact pin 100b according to the second preferred embodiment of the present invention, and FIG. 14B is a cross-sectional view taken along line A-A′ of FIG. 14A.

The electrically conductive contact pin 100b comprises a first end region 110b, a second end region 120b, and a body region 130b positioned between the first and second end regions 110b and 120b. The first end region 110b is a region connected to the connection pad of a space transformer, and the second end region 120b is a region connected to the external terminal of a semiconductor wafer. The body region 130b is a region that deforms with varying curvature in the longitudinal direction (±y direction) under the pressing force applied through both end regions.

The body region 130b includes at least two beam portions 131b. The beam portions 131b are spaced apart from each other by the slit 132b. The beam portions 131b located on both sides of the slit 132b are separated or detached from each other.

The slit 132b is formed to extend in the width direction (±x direction) of the body region 130b. Additionally, a plurality of slits 132b may be provided, spaced apart from each other in the width direction, and, for example, there may be seven slits 132b.

A functional layer 133b is provided inside the slit 132b. The beam portions 131b and the functional layer 133b are alternately arranged along the longitudinal direction (±y direction). Furthermore, the beam portions 131b and the functional layer 133b are arranged parallel to each other.

Each slit 132b has a length in the width direction (±x direction) and a length in the longitudinal direction (±y direction). Here, since the length in the longitudinal direction (±y direction) of the slit 132b is shorter than the length in the width direction (±x direction), the length of the functional layer 133b in the width direction (±x direction) is longer than its length in the longitudinal direction (±y direction).

The beam portions 131b are provided with a plurality of mutually different metal layers stacked, and the functional layer 133b may be formed of a single metal. The beam portions 131b are provided with a plurality of metal layers stacked in the thickness direction (±z direction). The plurality of metal layers include a first metal layer 101 and a second metal layer 102.

The first metal layer 101 is a metal with relatively high wear resistance or elastic modulus compared to the second metal layer 102 and is preferably formed of a metal selected from rhodium (Rh), platinum (Pt), iridium (Ir), palladium (Pd), nickel (Ni), manganese (Mn), tungsten (W), phosphorus (P), or alloys thereof, or palladium-cobalt (PdCo) alloy, palladium-nickel (PdNi) alloy, nickel-phosphorus (NiP) alloy, nickel-manganese (NiMn), nickel-cobalt (NiCo), or nickel-tungsten (NiW) alloy. The second metal layer 102 is a metal with relatively high electrical conductivity compared to the first metal layer 101 and is preferably formed of a metal selected from copper (Cu), silver (Ag), gold (Au), or alloys thereof.

The first metal layer 101 is provided on the lower and upper surfaces in the thickness direction (±z direction) of the electrically conductive contact pin 100b, and the second metal layer 102 is provided between the first metal layers 101. For example, the beam portions 131b are alternately stacked in the order of the first metal layer 101, the second metal layer 102, and the first metal layer 101, and the number of stacked layers may be three or more.

The functional layer 133b may be formed of a metal selected from copper (Cu), silver (Ag), gold (Au), or alloys thereof.

The second metal layer 102 constituting the beam portions 131b and the functional layer 133b may be made of the same metal material. For example, the second metal layer 102 and the functional layer 133b may be formed of the same metal selected from copper (Cu), silver (Ag), or gold (Au).

Alternatively, the second metal layer 102 constituting the beam portions 131b and the functional layer 133b may be made of different metal materials. For example, when the second metal layer 102 is formed of one metal selected from copper (Cu), silver (Ag), or gold (Au), the functional layer 133b may be formed of a different material from the second metal layer 102 and may be formed of another metal selected from copper (Cu), silver (Ag), or gold (Au).

The first end region 110b and/or the second end region 120b may be formed by stacking a plurality of metal layers, including the first metal layer 101 and the second metal layer 102, considering the current carrying capacity (CCC). In this case, the first end region 110b and/or the second end region 120b may be configured by integrally extending the first metal layer 101 and the second metal layer 102 constituting the beam portions 131b.

Alternatively, the first end region 110b and/or the second end region 120b may be formed of a metal material different from that of the beam portions 131b, considering wear resistance. For example, the first end region 110b and/or the second end region 120b may be formed of a single material selected from rhodium (Rh), platinum (Pt), iridium (Ir), palladium (Pd), nickel (Ni), manganese (Mn), tungsten (W), phosphorus (P), or alloys thereof, or palladium-cobalt (PdCo) alloy, palladium-nickel (PdNi) alloy, nickel-phosphorus (NiP) alloy, nickel-manganese (NiMn), nickel-cobalt (NiCo), or nickel-tungsten (NiW) alloy.

The functional layer 133b has higher electrical conductivity than the beam portions 131b. Regardless of whether the beam portions 131b are composed of a single metal layer or a plurality of metal layers including the first and second metal layers 101 and 102, the functional layer 133b has higher electrical conductivity than the beam portions 131b. Here, when the beam portions 131b are composed of a plurality of metal layers, the electrical conductivity of the beam portions 131b refers to the average electrical conductivity of the plurality of metal layers.

The functional layer 133b has a lower elastic modulus than the beam portions 131b. Regardless of whether the beam portions 131b are composed of a single metal layer or a plurality of metal layers including the first and second metal layers 101 and 102, the functional layer 133b has a lower elastic modulus than the beam portions 131b. Here, when the beam portions 131b are composed of a plurality of metal layers, the elastic modulus of the beam portions 131b refers to the average elastic modulus of the plurality of metal layers.

The functional layer 133b contacts a plurality of metal layers provided in the thickness direction (±z direction) of the beam portions 131b at the bonding surface with the beam portions 131b. The beam portions 131b are configured by alternately stacking the first metal layer 101 and the second metal layer 102. Through this, the second metal layers 102 of the beam portions 131b, which have high electrical conductivity, are connected to the functional layer 133b, which also has high electrical conductivity. In a structure without the functional layer 133b, the second metal layers 102 constituting the beam portions 131b are disconnected in the thickness direction (±z direction) by the first metal layer 101. However, according to the embodiment of the present invention, the second metal layers 102 constituting the beam portions 131b are connected to each other by the functional layer 133b, thereby forming a structure in which the second metal layers 102 are electrically connected to each other. Through this, the current carrying capacity (CCC) of the electrically conductive contact pin 100b can be improved.

Meanwhile, if the inside of the slit 132b is left empty, stress may be concentrated at the ends of the slit 132b due to the abrupt change in cross-sectional area, which may result in local failure of the beam portions 131b. However, according to the embodiment of the present invention, by providing the functional layer 133b inside the slit 132b, the abrupt increase in stress at the ends of the slit 132b is prevented, thereby preventing local failure of the slit 132b.

As described above, the present invention improves the current carrying capacity (CCC) and prevents local failure of the slit 132b by forming the beam portions 131b with multilayer plating of the first and second metal layers 101 and 102 to lower the elastic modulus and prevent an increase in contact pressure, and by providing the functional layer 133b inside the slit 132b, wherein the functional layer 133b is formed of at least one metal with high electrical conductivity, such as copper (Cu), silver (Ag), or gold (Au).

### Electrically Conductive Contact Pin 100c According to the Third Embodiment

The electrically conductive contact pin 100c according to the third embodiment may be a socket pin used in a test socket. More specifically, the electrically conductive contact pin 100c may be a pin used to inspect a semiconductor package, installed by being inserted into a guide hole of a guide housing 150c.

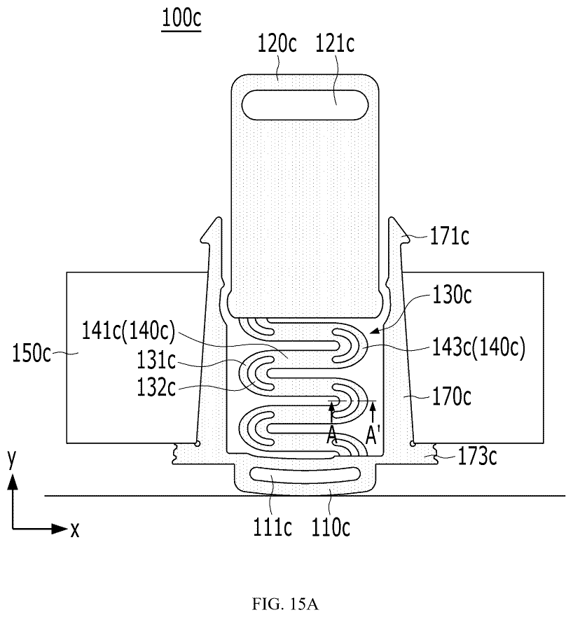

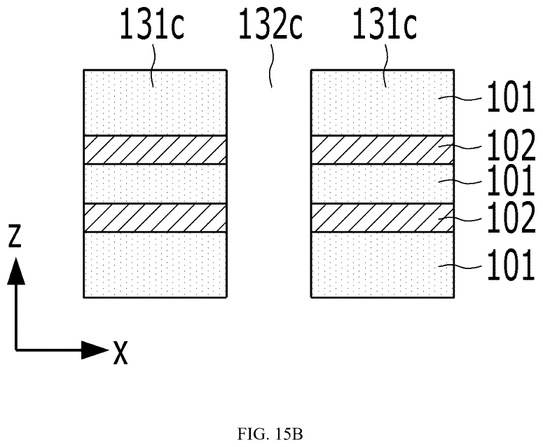

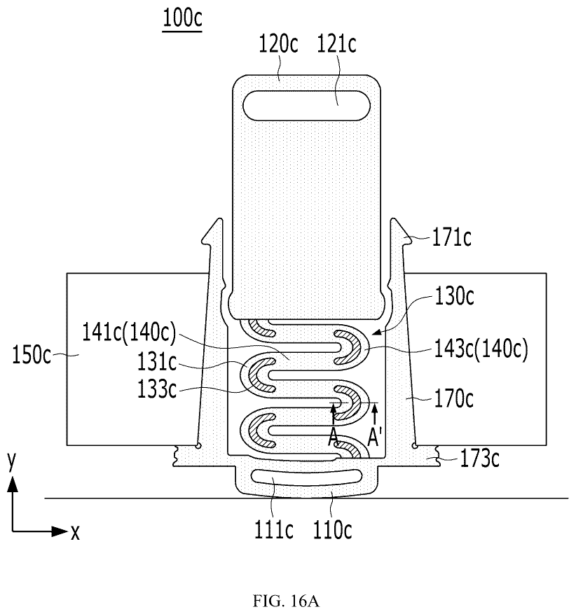

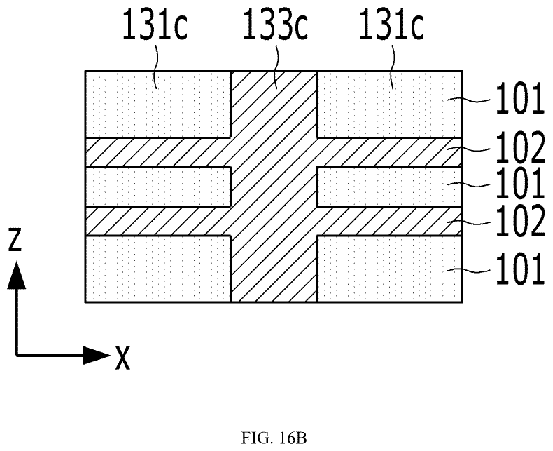

Hereinafter, the electrically conductive contact pin 100c according to the third preferred embodiment of the present invention will be described with reference to FIGS. 15A to 16B. FIG. 15A is a plan view of the electrically conductive contact pin 100c before the functional layer 133c is provided in the slit 132c in the electrically conductive contact pin 100c according to the third preferred embodiment of the present invention, and FIG. 15B is a cross-sectional view taken along line A-A′ of FIG. 15A. FIG. 16A is a plan view of the electrically conductive contact pin 100c according to the third preferred embodiment of the present invention, and FIG. 16B is a cross-sectional view taken along line A-A′ of FIG. 16A.

The electrically conductive contact pin 100c comprises a first end region 110c, a second end region 120c, and a body region 130c positioned between the first and second end regions 110c and 120c. The first end region 110c is a region connected to the connection pad of a circuit board, and the second end region 120c is a region connected to the external terminal of a semiconductor package. The body region 130c is a region that deforms under the pressing force applied through both end regions.

The body region 130c includes a spring portion 140c having a curved portion 143c. The spring portion 140c is formed by alternately connecting a plurality of straight portions 141c and a plurality of curved portions 143c. The straight portions 141c connect the left and right adjacent curved portions 143c, and the curved portions 143c connect the upper and lower adjacent straight portions 141c. The curved portions 143c are provided in an arc shape.

The spring portion 140c of the body region 130c comprises at least two beam portions 131c. The beam portions 131c are spaced apart from each other by a slit 132c. The beam portions 131c located on both sides of the slit 132c, with the slit 132c in between, are separated or detached from each other.

The slit 132c may be provided only in the curved portion 143c and may not be provided in the straight portion 141c. A plurality of slits 132c provided in the curved portion 143c may be spaced apart from each other in the width direction and may be provided in plurality. However, only one slit 132c is illustrated in the drawings. Meanwhile, although not shown in the drawings, the slit 132c may be provided only in the straight portion 141c and not in the curved portion 143c, or the slit 132c may be provided in both the straight portion 141c and the curved portion 143c.

A functional layer 133c is provided inside the slit 132c.

The beam portion 131c is provided with a plurality of different metal layers stacked, and the functional layer 133c may be formed of a single metal. The beam portion 131c is provided with a plurality of metal layers stacked in the thickness direction (±z direction). The plurality of metal layers include a first metal layer 101 and a second metal layer 102.

The first metal layer 101 is a metal having relatively higher wear resistance or elastic modulus compared to the second metal layer 102, and preferably, it may be formed of a metal selected from rhodium (Rh), platinum (Pt), iridium (Ir), palladium (Pd), nickel (Ni), manganese (Mn), tungsten (W), phosphorus (P) or alloys thereof, or palladium-cobalt (PdCo) alloy, palladium-nickel (PdNi) alloy, nickel-phosphorus (NiP) alloy, nickel-manganese (NiMn), nickel-cobalt (NiCo), or nickel-tungsten (NiW) alloy. The second metal layer 102 is a metal having relatively higher electrical conductivity compared to the first metal layer 101, and preferably, it may be formed of a metal selected from copper (Cu), silver (Ag), gold (Au), or alloys thereof.

The first metal layer 101 is provided on the lower and upper surfaces in the thickness direction (±z direction) of the electrically conductive contact pin 100b, and the second metal layer 102 is provided between the first metal layers 101. For example, the beam portion 131c is alternately stacked in the order of the first metal layer 101, the second metal layer 102, and the first metal layer 101, and the number of stacked layers may be configured to be three or more.

The functional layer 133c may be formed of a metal selected from copper (Cu), silver (Ag), gold (Au), or alloys thereof.

The second metal layer 102 constituting the beam portion 131c and the functional layer 133c may be made of the same metal material. For example, the second metal layer 102 and the functional layer 133c may be formed of the same metal selected from copper (Cu), silver (Ag), and gold (Au).

Alternatively, the second metal layer 102 constituting the beam portion 131c and the functional layer 133c may be made of different metal materials. For example, when the second metal layer 102 is one metal selected from copper (Cu), silver (Ag), and gold (Au), the functional layer 133c may be formed of a different material from the second metal layer 102 and may be formed of another metal selected from copper (Cu), silver (Ag), and gold (Au).

The first end region 110c and/or the second end region 120c may be formed by stacking a plurality of metal layers, including the first metal layer 101 and the second metal layer 102, in consideration of the current carrying capacity (CCC). In this case, the first end region 110c and/or the second end region 120c may be configured such that the first metal layer 101 and the second metal layer 102 constituting the beam portion 131c are integrally extended.

Alternatively, the first end region 110c and/or the second end region 120c may be formed of a metal material different from that of the beam portion 131c in consideration of wear resistance. For example, the first end region 110c and/or the second end region 120c may be formed of a single material selected from rhodium (Rh), platinum (Pt), iridium (Ir), palladium (Pd), nickel (Ni), manganese (Mn), tungsten (W), phosphorus (P) or alloys thereof, or palladium-cobalt (PdCo) alloy, palladium-nickel (PdNi) alloy, nickel-phosphorus (NiP) alloy, nickel-manganese (NiMn), nickel-cobalt (NiCo), or nickel-tungsten (NiW) alloy.

The functional layer 133c has an electrical conductivity higher than that of the beam portion 131c. Regardless of whether the beam portion 131c is composed of a single metal layer or a plurality of metal layers including the first and second metal layers 101 and 102, the functional layer 133c has an electrical conductivity higher than that of the beam portion 131c. Here, in the case where the beam portion 131c is composed of a plurality of metal layers, the electrical conductivity of the beam portion 131c refers to the average electrical conductivity of the plurality of metal layers.

The functional layer 133c has an elastic modulus lower than that of the beam portion 131c. Regardless of whether the beam portion 131c is composed of a single metal layer or a plurality of metal layers including the first and second metal layers 101 and 102, the functional layer 133c has an elastic modulus lower than that of the beam portion 131c. Here, in the case where the beam portion 131c is composed of a plurality of metal layers, the elastic modulus of the beam portion 131c refers to the average elastic modulus of the plurality of metal layers.

The functional layer 133c contacts a plurality of metal layers provided in the thickness direction (±z direction) of the beam portion 131c at the bonding surface with the beam portion 131c. The beam portion 131c is configured by alternately stacking metal layers with relatively high hardness and metal layers with relatively high electrical conductivity, and the functional layer 133c with high electrical conductivity contacts the side surface of the beam portion 131c. Through this, the metal layers of the beam portion 131c with high electrical conductivity are connected to the functional layer 133c with high electrical conductivity, thereby improving the current carrying capacity (CCC) of the electrically conductive contact pin 100c.

If the inside of the slit 132c is left empty, stress may concentrate at the end of the slit 132c due to a sudden change in cross-sectional area, which may result in local failure of the beam portion 131c. However, according to the embodiment of the present invention, by providing the functional layer 133c inside the slit 132c, a sudden increase in stress at the end of the slit 132c is prevented, thereby preventing local failure of the beam portion 131c.

The electrically conductive contact pin 100c further comprises a support portion 170c. The support portion 170c comprises an upper locking portion 171c and a lower locking portion 173c. The upper locking portion 171c is provided at the upper part of the support portion 170c to prevent the electrically conductive contact pin 100c from falling downward from the guide housing 150c. The lower locking portion 173c is provided at the lower part of the support portion 170c to prevent the electrically conductive contact pin 100c from falling upward from the guide housing 150c. The upper locking portion 171c can rest on the upper surface of the guide housing 150c, and the lower locking portion 173c can rest on the lower surface of the guide housing 150c.

The first end region 110c is provided with a first hollow portion 111c. When the first end region 110c is in contact with the pad of the circuit board, the first hollow portion 111c allows elastic deformation of the first end region 110c. The second end region 120c is provided with a second hollow portion 121c. When the second end region 120c is in contact with the terminal of the semiconductor package, the second hollow portion 121c allows elastic deformation of the second end region 120c.

The first end region 110c, the second end region 120c, the body region 130c, and the support portion 170c of the electrically conductive contact pin 100c are integrally provided. The first end region 110c, the second end region 120c, the body region 130c, and the support portion 170c are manufactured simultaneously using a plating process. The electrically conductive contact pin 100c is manufactured as an integral structure in which the first end region 110c, the second end region 120c, the body region 130c, and the support portion 170c are connected to each other by proceeding in the same process sequence as the manufacturing method of the first embodiment described above.

The guide housing 150c is composed of a material such as silicon nitride (Si₃N₄) or polyimide (PI). In this case, the guide hole formed in the guide housing 150c is processed and formed using a laser. Since the guide hole is formed using a laser, the upper width and lower width of the guide hole differ depending on the thickness of the guide housing 150c, but the difference is approximately 10 μm or more and less than 20 μm. That is, the guide hole formed in the guide housing 150c has a trapezoidal cross-sectional shape with an inclined surface. To ensure that the outer wall of the support portion 170c can closely adhere to such a guide hole, the outer wall of the support portion 170c is also provided in an inclined shape corresponding to the inclined structure of the guide hole. Through this, the support portion 170c closely adheres to the guide hole of the guide housing 150c without any clearance, thereby preventing the electrically conductive contact pin 100c from being detached from the guide housing 150c during inspection and ensuring that the contact points with the connection pad of the circuit board and/or the external terminal of the semiconductor package do not shift during inspection.

As described above, although the preferred embodiments of the present invention have been described with reference to the accompanying drawings, those skilled in the art may variously modify or change the present invention within the scope and spirit of the invention as set forth in the following claims.

What is claimed is:

1. An electrically conductive contact pin comprising a first end region, a second end region, and a body region positioned between the first and second end regions, wherein the body region includes at least two beam portions, and adjacent beam portions are spaced apart from each other by a slit,
the electrically conductive contact pin comprising a functional layer provided inside the slit.

2. The electrically conductive contact pin of claim 1, wherein the functional layer has an electrical conductivity greater than an electrical conductivity of the beam portion.

3. The electrically conductive contact pin of claim 1, wherein the functional layer has an elastic modulus smaller than an elastic modulus of the beam portion.

4. The electrically conductive contact pin of claim 1, wherein the beam portion is provided with a plurality of different metal layers stacked, and the functional layer is formed of a single metal layer.

5. The electrically conductive contact pin of claim 1, wherein the beam portion includes a first metal layer and a second metal layer,
the first metal layer is formed of a metal selected from rhodium (Rh), platinum (Pt), iridium (Ir), palladium (Pd), nickel (Ni), manganese (Mn), tungsten (W), phosphorus (P) or alloys thereof, or palladium-cobalt (PdCo) alloy, palladium-nickel (PdNi) alloy, nickel-phosphorus (NiP) alloy, nickel-manganese (NiMn), nickel-cobalt (NiCo), or nickel-tungsten (NiW) alloy,
the second metal layer is formed of a metal selected from copper (Cu), silver (Ag), gold (Au), or alloys thereof, and
the functional layer is formed of a metal selected from copper (Cu), silver (Ag), gold (Au), or alloys thereof.

6. The electrically conductive contact pin of claim 1, wherein the functional layer is composed of a different material from a metal layer constituting the beam portion.

7. The electrically conductive contact pin of claim 1, wherein the functional layer has the same material as any one of a plurality of metal layers constituting the beam portion.

8. The electrically conductive contact pin of claim 1, wherein the functional layer contacts a plurality of metal layers provided in a height direction of the beam portion at a bonding surface with the beam portion.

9. The electrically conductive contact pin of claim 1, wherein the functional layer is provided entirely in the slit.

10. The electrically conductive contact pin of claim 1, wherein the functional layer is provided partially among a plurality of the slits.

11. The electrically conductive contact pin of claim 1, wherein the functional layer is provided partially in a length direction of the slit.

12. The electrically conductive contact pin of claim 1, wherein the functional layer is provided partially in a thickness direction of the slit.

13. The electrically conductive contact pin of claim 1, wherein the beam portion is elastically deformed by a pressing force applied to the electrically conductive contact pin.

14. The electrically conductive contact pin of claim 1, wherein the beam portion and the functional layer are alternately arranged.

15. The electrically conductive contact pin of claim 1, wherein the beam portion and the functional layer are arranged parallel to each other.

16. The electrically conductive contact pin of claim 1, wherein the body region includes a spring portion having a curved portion,
and the slit is provided in the curved portion
